(19) United States
(12) Patent Application Publication
(10) Pub. No.: US 2026/0136570 A1
(43) Pub. Date: May 14, 2026

(54) SIGNAL TRANSMISSION DEVICE

(71) Applicant: DENSO CORPORATION, Kariya-city (JP)

(72) Inventors: Koichi YAKO, Kariya-city (JP); Shuji ASANO, Kariya-city (JP); Shinichiro YANAGI, Kariya-city (JP); Tomohiro SAITO, Kariya-city (JP)

(21) Appl. No.: 19/443,659

(22) Filed: Jan. 8, 2026

Related U.S. Application Data
(63) Continuation of application No. PCT/JP2024/023390, filed on Jun. 27, 2024.

(30) Foreign Application Priority Data
Jul. 13, 2023 (JP) 2023-115253

(51) Int. Cl. H10D 1/68; H10D 84/00

(52) U.S. Cl. CPC H10D 1/714; H10D 84/201

(57) ABSTRACT

A signal transmission device includes a semiconductor substrate, an insulating film, a first electrode, a second electrode, a ground, and a lead-out portion. The lead-out portion includes a connection portion connected to the first electrode, a first extension portion connected to the connection portion, and a second extension portion connected to the first extension portion and an electronic circuit. The first extension portion extends in a direction that intersects a shortest direction of a line segment connecting the connection portion and the ground in a direction perpendicular to a thickness direction. The second extension portion extends in a direction intersecting the direction in which the first extension portion extends. The signal transmission device is configured so that signals from the electronic circuit are transmitted via the second extension portion, the first extension portion, the connection portion, the first electrode, and a second electrode.

### CROSS REFERENCE TO RELATED APPLICATIONS

The present application is a continuation application of International Patent Application No. PCT/JP 2024/023391 filed on Jun. 27, 2024, which designated the U.S. and claims the benefit of priority from Japanese Patent Application No. 2023-115254 filed on Jul. 13, 2023. The entire disclosures of all of the above applications are incorporated herein by reference.

### TECHNICAL FIELD

The present disclosure relates to a signal transmission device.

### BACKGROUND

Conventionally, a capacitor is known which includes a first terminal as a first electrode, a second terminal as a second electrode, and a dielectric material layer disposed between the first terminal and the second terminal.

### SUMMARY

A signal transmission device according to an aspect of the present disclosure includes a semiconductor substrate, an insulating film having electrical insulating properties and disposed on the semiconductor substrate, a first electrode covered with the insulating film, a second electrode disposed on the insulating film, facing the first electrode in a thickness direction of the semiconductor substrate, and to which a voltage higher than a voltage applied to the first electrode is to be applied, a ground disposed between an electronic circuit and both the first electrode and the second electrode in a direction perpendicular to the thickness direction, and having a potential set to a reference potential, and a lead-out portion including a connection portion connected to the first electrode, a first extension portion connected to the connection portion, and a second extension portion connected to the first extension portion and to the electronic circuit. The first extension portion may extend in a direction that intersects a shortest direction of a line segment connecting the connection portion and the ground in the direction perpendicular to the thickness direction. The second extension portion may extend in a direction intersecting the direction in which the first extension portion extends. The signal transmission device may be configured so that signals from the electronic circuit are transmitted via the second extension portion, the first extension portion, the connection portion, the first electrode, and the second electrode.

### BRIEF DESCRIPTION OF DRAWINGS

Objects, features and advantages of the present disclosure will become apparent from the following detailed description made with reference to the accompanying drawings. In the drawings:

FIG. 1 is a top layout view of a signal transmission device according to a first embodiment;

FIG. 2 is a cross-sectional view taken along line II-II of FIG. 1;

FIG. 3 is a diagram showing a first lower electrode and a first lead-out wiring of a signal transmission device;

FIG. 4 is a diagram showing a second lower electrode and a second lead-out wiring of the signal transmission device;

FIG. 5 is a diagram showing a potential distribution of a signal transmission device of a comparative example;

FIG. 6 is a diagram showing a potential distribution of the signal transmission device of the comparative example;

FIG. 7 is a diagram showing an electric field distribution of the signal transmission device of the comparative example;

FIG. 8 is a diagram showing an electric field distribution of the signal transmission device of the comparative example;

FIG. 9 is a diagram showing maximum electric field strengths in the first embodiment, a second embodiment, and a comparative example;

FIG. 10 is a cross-sectional view of a first lower electrode and a first lead-out wiring of a signal transmission device according to the second embodiment;

FIG. 11 is a diagram showing a second lower electrode and a second lead-out wiring of the signal transmission device according to the second embodiment;

FIG. 12 is a top layout view of a signal transmission device according to a third embodiment;

FIG. 13 is a diagram showing a first lower electrode and a third lead-out wiring of the signal transmission device according to the third embodiment;

FIG. 14 is a diagram showing a second lower electrode and a fourth lead-out wiring of the signal transmission device according to the third embodiment;

FIG. 15 is a top layout view of a signal transmission device according to a fourth embodiment; and

FIG. 16 is a top layout view of a signal transmission device according to a fifth embodiment.

### DETAILED DESCRIPTION

In a capacitor having a first terminal, a second terminal, and a dielectric material layer disposed between the first terminal and the second terminal, increasing the thickness of the dielectric material layer between the first terminal and the second terminal can reduce the electric field strength between the first terminal and the second terminal. Accordingly, an insulation withstand voltage of the capacitor as a signal transmission device can be ensured. However, increasing the thickness of the dielectric material layer increases the number of manufacturing steps, such as forming a large number of vias and wiring layers, in the manufacture of the capacitor. This increases the cost of the capacitor. Furthermore, if the thickness of the dielectric material layer is small, the electric field strength between the first terminal and the second terminal increases, and therefore the insulation withstand voltage of the capacitor cannot be ensured.

A signal transmission device according to an aspect of the present disclosure includes a semiconductor substrate, an insulating film having electrical insulating properties and disposed on the semiconductor substrate, a first electrode covered with the insulating film, a second electrode disposed on the insulating film, facing the first electrode in a thickness direction of the semiconductor substrate, and to which a voltage higher than a voltage applied to the first electrode is to be applied, a ground disposed between an electronic circuit and both the first electrode and the second electrode in a direction perpendicular to the thickness direction, and having a potential set to a reference potential, and a lead-out portion including a connection portion connected to the first electrode, a first extension portion connected to the connection portion, and a second extension portion connected to the first extension portion and to the electronic circuit. The first extension portion extends in a direction that intersects a shortest direction of a line segment connecting the connection portion and the ground in the direction perpendicular to the thickness direction. The second extension portion extends in a direction intersecting the direction in which the first extension portion extends. The signal transmission device is configured so that signals from the electronic circuit are transmitted via the second extension portion, the first extension portion, the connection portion, the first electrode, and the second electrode.

The strength of the electric field from the second electrode is smaller in a direction not directed from the second electrode toward the ground than in a direction directed from the second electrode toward the ground. Furthermore, since the first extension portion extends in the direction intersecting the shortest direction, the lead-out portion extends in the direction not directed from the second electrode toward the ground. Therefore, the electric field strength between the second electrode and the lead-out portion is smaller than when the first extension portion extends in the shortest direction. Furthermore, it is not necessary to increase the thickness of the insulating film between the first electrode and the second electrode. Therefore, while suppressing an increase in the thickness between the electrodes, the insulation withstand voltage of the signal transmission device can be ensured.

Hereinafter, embodiments will be described with reference to the drawings. In the following embodiments, the same or equivalent portions are denoted by the same reference numerals, and the description thereof will be omitted.

### FIRST EMBODIMENT

In a signal transmission device of the present embodiment, an increase in thickness between electrodes is suppressed, while ensuring the insulation withstand voltage of the signal transmission device.

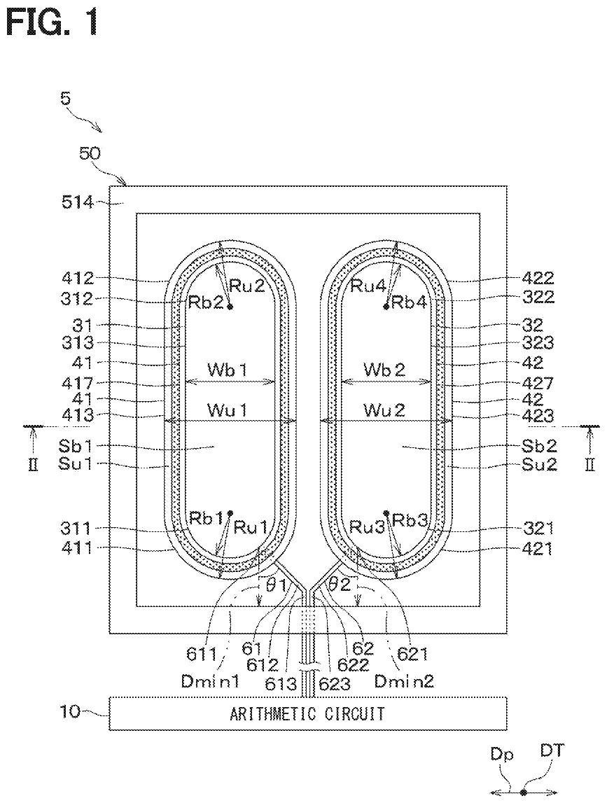

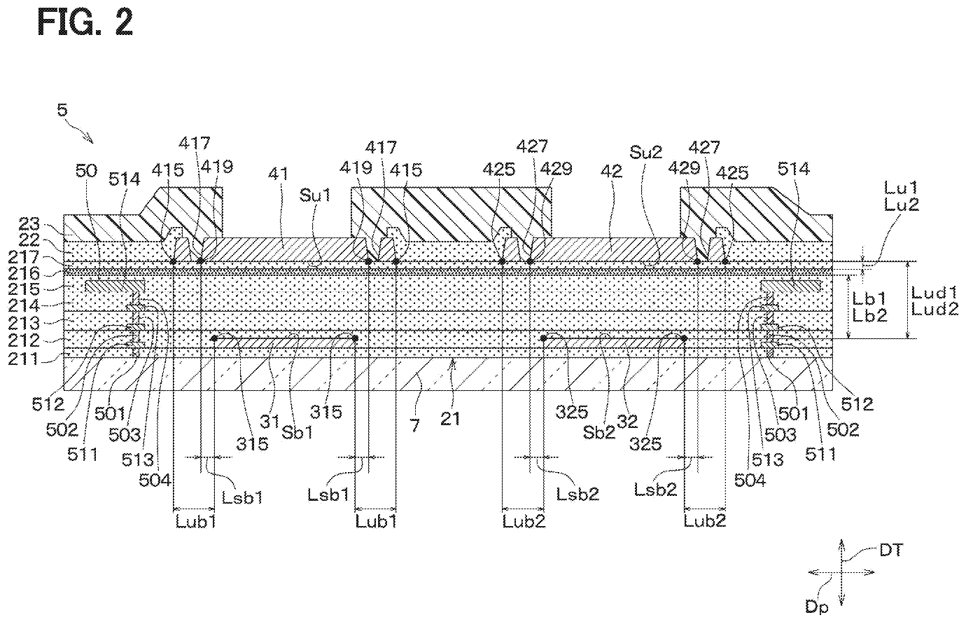

Specifically, as shown in FIG. 1 and FIG. 2, a signal transmission device 5 includes a semiconductor substrate 7, an arithmetic circuit 10, a first insulating film 21, a first lower electrode 31, a first upper electrode 41, a shield portion 50, and a first lead-out wiring 61. Furthermore, the signal transmission device 5 includes a second lower electrode 32, a second upper electrode 42, a second lead-out wiring 62, a second insulating film 22, and a third insulating film 23.

The semiconductor substrate 7 is made of, for example, silicon or the like. Hereinafter, a thickness direction DT of the semiconductor substrate 7 will be simply referred to as the thickness direction DT.

The arithmetic circuit 10 is, for example, a microcontroller or the like disposed on the semiconductor substrate 7, and is an electronic circuit that performs arithmetic operations and logical operations.

As shown in FIG. 2, the first insulating film 21 has electrical insulating properties and is disposed on the semiconductor substrate 7. The first insulating film 21 includes a first film 211, a second film 212, a third film 213, a fourth film 214, a fifth film 215, a sixth film 216, and a seventh film 217. In the example shown in FIG. 2, the first insulating film 21 has a seven-layer structure. However, the number of layers of the first insulating film 21 is not limited to seven and may be any number.

The first film 211 is disposed on the semiconductor substrate 7. The second film 212 is disposed on the first film 211. The third film 213 is disposed on the second film 212. The fourth film 214 is disposed on the third film 213. The fifth film 215 is disposed on the fourth film 214. The sixth film 216 is disposed on the fifth film 215. The seventh film 217 is disposed on the sixth film 216. Furthermore, the fifth film 215 is connected in the thickness direction DT to a surface of the sixth film 216 opposite the seventh film 217, and is also connected in the thickness direction DT to the first lower electrode 31 and the second lower electrode 32, which will be described later, via the second film 212, the third film 213, and the fourth film 214. In addition, the sixth film 216 is connected in the thickness direction DT to a surface of the seventh film 217 opposite the first upper electrode 41 and the second upper electrode 42, which will be described later. Furthermore, the seventh film 217 is connected in the thickness direction DT to the first upper electrode 41 and the second upper electrode 42, which will be described later.

Additionally, the first film 211, the second film 212, the third film 213, the fourth film 214, the fifth film 215, and the seventh film 217 are made of silicon dioxide or the like, and thus are oxide films. Furthermore, the sixth film 216 is made of silicon nitride or the like, and thus is a nitride film.

Since the first lower electrode 31 is disposed on the first film 211, the first lower electrode 31 is covered with the first insulating film 21. In addition, the first lower electrode 31 is made of a metal such as aluminum, tungsten, copper, titanium, or tantalum, and therefore possesses electrical conductivity. Furthermore, a length of the first lower electrode 31 in the thickness direction DT, that is, a thickness of the first lower electrode 31, is, for example, set to 0.1 to 1.0 μm.

Additionally, in this example, a cross section of the first lower electrode 31 when cut in a direction perpendicular to the thickness direction DT is formed in an oval shape. Accordingly, as shown in FIG. 1, the first lower electrode 31 has a lower first curved portion 311, a lower second curved portion 312, and a lower first straight portion 313.

The lower first curved portion 311 is formed to be convexly curved toward the arithmetic circuit 10 in the direction perpendicular to the thickness direction DT. As a result, the center of curvature of the lower first curved portion 311 is located inside the first lower electrode 31. Furthermore, since the shape of the first lower electrode 31 is the oval shape, the lower first curved portion 311 is formed in an arc shape. In addition, a lower first radius Rb1 is, for example, set to be greater than or equal to 20 μm. It should be noted that the lower first radius Rb1 is a radius of the lower first curved portion 311.

The lower second curved portion 312 is formed so as to be convexly curved on the side opposite the arithmetic circuit 10 in the direction perpendicular to the thickness direction DT. Therefore, the center of curvature of the lower second curved portion 312 is located inside the first lower electrode 31. Furthermore, since the shape of the first lower electrode 31 is the oval shape, the lower second curved portion 312 is formed in an arc shape. In addition, a lower second radius Rb2 is, for example, set to be greater than or equal to 20 μm. Note that the lower second radius Rb2 is a radius of the lower second curved portion 312.

The lower first straight portion 313 is connected to the lower first curved portion 311 and the lower second curved portion 312. Furthermore, the lower first straight portion 313 extends in one direction that is perpendicular to the thickness direction DT. In addition, the lower first radius Rb1 and the lower second radius Rb2 are set to be no more than half of a lower first width Wb1; that is, Rb1≤Wb½ and Rb2≤Wb½. Note that the lower first width Wb1 is a length of the lower first straight portion 313 in the direction perpendicular to both the thickness direction DT and the direction in which the lower first straight portion 313 extends.

As shown in FIG. 2, the first upper electrode 41 is disposed on the seventh film 217, and thus is disposed on the first insulating film 21. In addition, the first upper electrode 41 is made of a metal such as aluminum, tungsten, copper, titanium, or tantalum, and therefore possesses electrical conductivity. Furthermore, a length of the first upper electrode 41 in the thickness direction DT, that is, a thickness of the first upper electrode 41, is, for example, set to 1.0 to 10.0 μm.

Additionally, a shape of a cross section of the first upper electrode 41 when cut in a direction perpendicular to the thickness direction DT corresponds to the shape of the first lower electrode 31. In this example, the cross section of the first upper electrode 41 is formed in an oval shape. Accordingly, as shown in FIG. 1, the first upper electrode 41 has an upper first curved portion 411, an upper second curved portion 412, and an upper first straight portion 413.

The upper first curved portion 411 is formed to be convexly curved toward the arithmetic circuit 10 in the direction perpendicular to the thickness direction DT. As a result, the center of curvature of the upper first curved portion 411 is located inside the first upper electrode 41. Furthermore, since the shape of the first upper electrode 41 is the oval shape, the upper first curved portion 411 is formed in an arc shape. In addition, an upper first radius Ru1 is, for example, set to be greater than or equal to 20 μm. It should be noted that the upper first radius Ru1 is a radius of the upper first curved portion 411.

The upper second curved portion 412 is formed to be convexly curved on the side opposite the arithmetic circuit 10 in the direction perpendicular to the thickness direction DT. Therefore, the center of curvature of the upper second curved portion 412 is located inside the first upper electrode 41. Furthermore, since the shape of the first upper electrode 41 is the oval shape, the upper second curved portion 412 is formed in an arc shape. In addition, an upper second radius Ru2 is, for example, set to be greater than or equal to 20 μm. It should be noted that the upper second radius Ru2 is a radius of the upper second curved portion 412.

The upper first straight portion 413 is connected to the upper first curved portion 411 and the upper second curved portion 412. Furthermore, the upper first straight portion 413 extends in the same direction as the lower first straight portion 313. In addition, the upper first radius Ru1 and the upper second radius Ru2 are each set to be no more than half of an upper first width Wu1. That is, Ru1≤Wu½ and Ru2≤Wu½. It should be noted that the upper first width Wu1 is a length of the upper first straight portion 413 in the direction perpendicular to both the thickness direction DT and the direction in which the upper first straight portion 413 extends.

Furthermore, as shown in FIG. 2, the first upper electrode 41 faces the first lower electrode 31 in the thickness direction DT. Therefore, a capacitor is formed between the first upper electrode 41 and the first lower electrode 31. In addition, a first inter-electrode distance Lud1 is set to be greater than or equal to 5.0 μm and less than or equal to 8.0 μm. It should be noted that the first inter-electrode distance Lud1 is a distance from the first upper electrode 41 to the first lower electrode 31 in the thickness direction DT.

Here, as shown in FIG. 1 and FIG. 2, an area of a surface of the first lower electrode 31 that is perpendicular to the thickness direction DT is referred to as a first lower area Sb1. Furthermore, an area of a surface of the first upper electrode 41 that is perpendicular to the thickness direction DT is referred to as a first upper area Su1. In addition, an end of a surface of the first lower electrode 31 that faces the first upper electrode 41 in the thickness direction DT and is positioned at an outer edge of the surface is referred to as the lower first electrode end 315. Furthermore, in the first upper electrode 41, an end that is positioned at an outer edge of the first upper electrode 41 in the direction perpendicular to the thickness direction DT and is in contact with the seventh film 217 is referred to as an upper first electrode end 415. Additionally, the minimum distance from the lower first electrode end 315 to the upper first electrode end 415 in the direction perpendicular to the thickness direction DT is referred to as a first end-to-end distance Lub1.

Then, the first upper area Su1 is set to be larger than the first lower area Sb1. That is, Su1>Sb1. Furthermore, in the direction perpendicular to the thickness direction DT, the lower first electrode end 315 is positioned further inside the first upper electrode 41 than the upper first electrode end 415. In addition, the first end-to-end distance Lub1 is set to be greater than or equal to 10 μm and less than or equal to 50 μm.

Furthermore, the first upper electrode 41 has a first slit 417 and a first slit end 419.

The first slit 417 is a hole that penetrates through the first upper electrode 41 in the thickness direction DT. In addition, the shape of a cross section obtained by cutting the first slit 417 in the direction perpendicular to the thickness direction DT corresponds to the shape of the first upper electrode 41. In this example, the cross section of the first slit 417 is formed in an oval shape. In FIG. 1, the first slit 417 is indicated with a dotted pattern to clearly show its location.

As shown in FIG. 2, the first slit end 419 is an outer edge of a side surface of the first upper electrode 41 that forms the first slit 417 and faces outward in the direction perpendicular to the thickness direction DT, and is in contact with the seventh film 217. Furthermore, in the direction perpendicular to the thickness direction DT, the first slit end 419 is positioned farther outside the first lower electrode 31 than the lower first electrode end 315. In addition, a first slit distance Lsb1 is set to be greater than or equal to 1.0 μm and less than or equal to 50 μm. It should be noted that the first slit distance Lsb1 is the minimum distance from the first slit end 419 to the lower first electrode end 315 in the direction perpendicular to the thickness direction DT.

Furthermore, a distance from the first lower electrode 31 to a surface of the sixth film 216 that faces the first lower electrode 31 in the thickness direction DT is referred to as a lower first distance Lb1. In addition, a distance from the first upper electrode 41 to a surface of the sixth film 216 that faces the first upper electrode 41 in the thickness direction DT is referred to as an upper first distance Lu1.

Then, the upper first distance Lu1 is set to be smaller than the lower first distance Lb1. That is, Lu1<Lb1.

Returning to FIG. 1, a portion of the shield portion 50 is disposed between the first lower electrode 31 and the first upper electrode 41, and the arithmetic circuit 10 in the direction perpendicular to the thickness direction DT. In addition, a potential of the shield portion 50 is set to a reference potential. Furthermore, as shown in FIG. 2, the shield portion 50 includes a first via 501, a first conductor 511, a second via 502. a second conductor 512, a third via 503, a third conductor 513, a fourth via 504, and a fourth conductor 514.

The first via 501 is formed by filling a via hole, which is formed in the first film 211, with a metal such as tungsten using CVD or the like. It should be noted that CVD stands for Chemical Vapor Deposition.

The first conductor 511 is connected to the first via 501 in the thickness direction DT. In addition, the first conductor 511 is formed together with the first lower electrode 31, and is made of a metal such as aluminum, tungsten, copper, titanium, or tantalum. Furthermore, the first conductor 511 is covered with the second film 212.

The second via 502 is formed by filling a via hole, which is formed in the second film 212, with a metal such as tungsten using CVD or the like. Additionally, the second via 502 is connected to the first conductor 511 in the thickness direction DT.

The second conductor 512 is connected to the second via 502 in the thickness direction DT. Furthermore, the second conductor 512 is made of a metal such as aluminum, tungsten, copper, titanium, or tantalum. Additionally, the second conductor 512 is covered with the third film 213.

The third via 503 is formed by filling a via hole, which is formed in the third film 213, with a metal such as tungsten using CVD or the like. Furthermore, the third via 503 is connected to the second conductor 512 in the thickness direction DT.

The third conductor 513 is connected to the third via 503 in the thickness direction DT. Additionally, the third conductor 513 is made of a metal such as aluminum, tungsten, copper, titanium, or tantalum. Furthermore, the third conductor 513 is covered with the fourth film 214.

The fourth via 504 is formed by filling a via hole, which is formed in the fourth film 214, with a metal such as tungsten using CVD or the like. Additionally, the fourth via 504 is connected to the third conductor 513 in the thickness direction DT.

The fourth conductor 514 is connected to the fourth via 504 in the thickness direction DT. Furthermore, the fourth conductor 514 is made of a metal such as aluminum, tungsten, copper, titanium, or tantalum. Additionally, the fourth conductor 514 is covered with the fifth film 215. Furthermore, as shown in FIG. 1, the fourth conductor 514 is formed in a rectangular ring shape, thereby surrounding the first lower electrode 31 and the first upper electrode 41 in the direction perpendicular to the thickness direction DT. It should be noted that, while the shape of the fourth conductor 514 is described here as a rectangular ring, it is not limited thereto and may instead be a polygonal ring, a circular ring, an oval ring, or the like.

The first lead-out wiring 61 is formed together with the first lower electrode 31. Furthermore, the first lead-out wiring 61 is made of a metal such as aluminum, tungsten, copper, titanium, or tantalum, and therefore possesses electrical conductivity. The first lead-out wiring 61 includes a first connection portion 611, a first extension portion 612, and a second extension portion 613.

The first connection portion 611 is connected to the first lower electrode 31. and in this example, is connected to the lower first curved portion 311. It should be noted that the first connection portion 611 is not limited to being connected to the lower first curved portion 311, and may also be connected to the lower second curved portion 312 and the lower first straight portion 313.

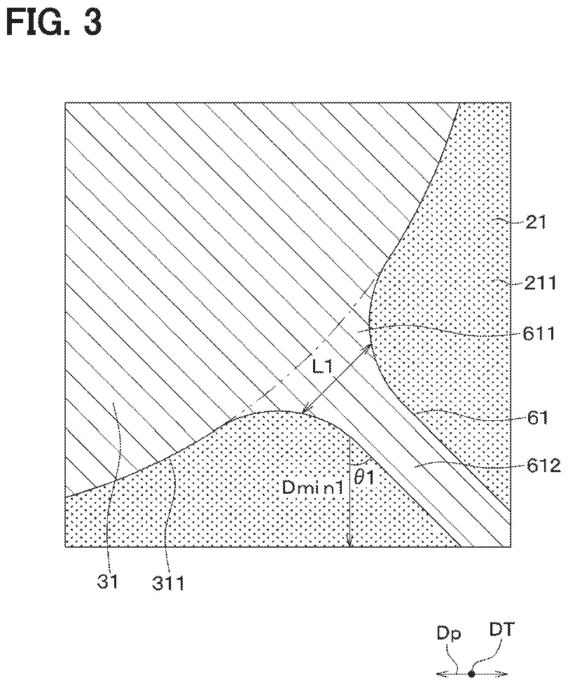

Furthermore, as shown in FIG. 3, an outer edge of the cross section of the first connection portion 611, when cut in the direction perpendicular to the thickness direction DT, is formed in a concavely curved shape. Therefore, the center of curvature of the first connection portion 611 is located outside of the first connection portion 611. In addition, the radius of curvature of the first connection portion 611 is, for example, set to 10 μm. Furthermore, a first length L1 decreases as the first connection portion 611 extends toward the first extension portion 612, which will be described later. It should be noted that the first length L1 is the length of the first connection portion 611 in a direction perpendicular to both the thickness direction DT and the direction in which the first extension portion 612 extends.

The first extension portion 612 is connected to a side of the first connection portion 611 opposite the first lower electrode 31. In addition, the first extension portion 612 extends in a direction intersecting a first shortest direction Dmin1. It should be noted that the first shortest direction Dmin1 is a direction of a shortest line segment connecting the first connection portion 611 and the shield portion 50 in a direction perpendicular to the thickness direction DT. Furthermore, in this example, the first extension portion 612 extends in a straight line. However, the way the first extension portion 612 extends is not limited to this example, and the first extension portion 612 may also extend in a curved shape.

Here, an angle formed by a straight line extending in the first shortest direction Dmin1 and a straight line extending in the direction in which the first extension portion 612 extends is defined as a first angle θ1. The first angle θ1 is set to be greater than or equal to 45 degrees and less than 90 degrees.

As shown in FIG. 1, the second extension portion 613 is connected to a side of the first extension portion 612 opposite the first connection portion 611. Furthermore, the second extension portion 613 extends in a direction that intersects with the direction in which the first extension portion 612 extends. For example, the second extension portion 613 extends in the first shortest direction Dmin1. As a result, the second extension portion 613 is connected to the arithmetic circuit 10. Here, the second extension portion 613 extends in a straight line. However, the way the second extension portion 613 extends is not limited to this example, and the second extension portion 613 may also extend in a curved shape.

Returning to FIG. 2, since the second lower electrode 32 is disposed on the first film 211, the second lower electrode 32 is covered with the first insulating film 21. In addition, the second lower electrode 32 is made of a metal such as aluminum, tungsten, copper, titanium, or tantalum, and therefore possesses electrical conductivity. Furthermore, a length of the second lower electrode 32 in the thickness direction DT, that is, a thickness of the second lower electrode 32, is, for example, set to 0.1 to 1.0 μm.

In addition, in this example, the cross section of the second lower electrode 32, when cut in the direction perpendicular to the thickness direction DT, is formed in an oval shape. Accordingly, as shown in FIG. 1, the second lower electrode 32 has a lower third curved portion 321, a lower fourth curved portion 322, and a lower second straight portion 323.

The lower third curved portion 321 is formed so as to be convexly curved toward the arithmetic circuit 10 in the direction perpendicular to the thickness direction DT. As a result, the center of curvature of the lower third curved portion 321 is located inside the second lower electrode 32. Furthermore, since the shape of the second lower electrode 32 is the oval shape, the lower third curved portion 321 is formed in an arc shape. In addition, a lower third radius Rb3 is, for example, set to be greater than or equal to 20 μm. It should be noted that the lower third radius Rb3 is a radius of the lower third curved portion 321.

The lower fourth curved portion 322 is formed so as to be convexly curved on the side opposite the arithmetic circuit 10 in the direction perpendicular to the thickness direction DT. Therefore, the center of curvature of the lower fourth curved portion 322 is located inside the second lower electrode 32. Furthermore, since the shape of the second lower electrode 32 is the oval shape, the lower fourth curved portion 322 is formed in an arc shape. In addition, a lower fourth radius Rb4 is, for example, set to be greater than or equal to 20 μm. It should be noted that the lower fourth radius Rb4 is a radius of the lower fourth curved portion 322.

The lower second straight portion 323 is connected to the lower third curved portion 321 and the lower fourth curved portion 322. Furthermore, the lower second straight portion 323 extends in the same direction as the lower first straight portion 313. In addition, the lower third radius Rb3 and the lower fourth radius Rb4 are set to be less than or equal to half of a lower second width Wb2, that is, Rb3≤Wb 2/2 and Rb4≤Wb 2/2. It should be noted that the lower second width Wb2 is a length of the lower second straight portion 323 in the direction perpendicular to both the thickness direction DT and the direction in which the lower second straight portion 323 extends.

Furthermore, the second lower electrode 32 is arranged alongside the first lower electrode 31 in the direction perpendicular to the thickness direction DT. Additionally, the second lower electrode 32 is surrounded by the shield portion 50 in the direction perpendicular to the thickness direction DT.

As shown in FIG. 2, the second upper electrode 42 is disposed on the seventh film 217, and therefore is disposed on the first insulating film 21. In addition, the second upper electrode 42 is made of a metal such as aluminum, tungsten, copper, titanium, or tantalum, and therefore possesses electrical conductivity. Furthermore, a length of the second upper electrode 42 in the thickness direction DT, that is, a thickness of the second upper electrode 42, is, for example, set to be 1.0 to 10.0 μm.

Additionally, the cross-sectional shape of the second upper electrode 42, when cut in the direction perpendicular to the thickness direction DT, corresponds to the shape of the second lower electrode 32, and in this example, is formed in an oval shape. Accordingly, as shown in FIG. 1, the second upper electrode 42 has an upper third curved portion 421, an upper fourth curved portion 422, and an upper second straight portion 423.

The upper third curved portion 421 is formed to be convexly curved toward the arithmetic circuit 10 in the direction perpendicular to the thickness direction DT. As a result, the center of curvature of the upper third curved portion 421 is located inside the second upper electrode 42. Furthermore, since the shape of the second upper electrode 42 is the oval shape, the upper third curved portion 421 is formed in an arc shape. In addition, an upper third radius Ru3 is, for example, set to be greater than or equal to 20 μm. It should be noted that the upper third radius Ru3 is a radius of the upper third curved portion 421.

The upper fourth curved portion 422 is formed to be convexly curved on the side opposite the arithmetic circuit 10 in the direction perpendicular to the thickness direction DT. Therefore, the center of curvature of the upper fourth curved portion 422 is located inside the second upper electrode 42. Furthermore, since the shape of the second upper electrode 42 is the oval shape, the upper fourth curved portion 422 is formed in an arc shape. In addition, an upper fourth radius Ru4 is, for example, set to be greater than or equal to 20 μm. It should be noted that the upper fourth radius Ru4 is a radius of the upper fourth curved portion 422.

The upper second straight portion 423 is connected to the upper third curved portion 421 and the upper fourth curved portion 422. Furthermore, the upper second straight portion 423 extends in the same direction as the lower second straight portion 323. In addition, the upper third radius Ru3 and the upper fourth radius Ru4 are set to be no more than half of an upper second width Wu2, that is, Ru3≤Wu 2/2 and Ru4≤Wu 2/2. It should be noted that the upper second width Wu2 is a length of the upper second straight portion 423 in the direction perpendicular to both the thickness direction DT and the direction in which the upper second straight portion 423 extends.

Furthermore, as shown in FIG. 2, the second upper electrode 42 faces the second lower electrode 32 in the thickness direction DT. Therefore, a capacitor is formed between the second upper electrode 42 and the second lower electrode 32. In addition, a second inter-electrode distance Lud2 is set to be greater than or equal to 5.0 μm and less than or equal to 8.0 μm. It should be noted that the second inter-electrode distance Lud2 is a distance from the second upper electrode 42 to the second lower electrode 32 in the thickness direction DT.

Furthermore, the second upper electrode 42 is arranged alongside the first upper electrode 41 in the direction perpendicular to the thickness direction DT. Additionally, as shown in FIG. 1, the second upper electrode 42 is surrounded by the shield portion 50 in the direction perpendicular to the thickness direction DT. Furthermore, a portion of the shield portion 50 is disposed between the second lower electrode 32 and the second upper electrode 42, and the arithmetic circuit 10 in the direction perpendicular to the thickness direction DT.

Here, as shown in FIG. 1 and FIG. 2, an area of the surface of the second lower electrode 32 in the direction perpendicular to the thickness direction DT is defined as a second lower area Sb2. Furthermore, an area of a surface of the second upper electrode 42 in the direction perpendicular to the thickness direction DT is defined as a second upper area Su2. In addition, an end of the surface of the second lower electrode 32 that faces the second upper electrode 42 in the thickness direction DT and is positioned at an outer edge of the surface is referred to as a lower second electrode end 325. Furthermore, in the second upper electrode 42, an end that is positioned at an outer edge of the second upper electrode 42 in the direction perpendicular to the thickness direction DT and is in contact with the seventh film 217 is referred to as an upper second electrode end 425. Additionally, the minimum distance from the lower second electrode end 325 to the upper second electrode end 425 in the direction perpendicular to the thickness direction DT is referred to as a second end-to-end distance Lub2.

Then, the second upper area Su2 is larger than the second lower area Sb2, that is, Su2>Sb2. Furthermore, the lower second electrode end 325 is positioned further inside the second upper electrode 42 than the upper second electrode end 425 in the direction perpendicular to the thickness direction DT. In addition, a second end-to-end distance Lub2 is set to be greater than or equal to 10 μm and less than or equal to 50 μm.

Furthermore, the second upper electrode 42 has a second slit 427 and a second slit end 429.

The second slit 427 is a hole that penetrates through the second upper electrode 42 in the thickness direction DT. In addition, the shape of a cross section obtained by cutting the second slit 427 in the direction perpendicular to the thickness direction DT corresponds to the shape of the second upper electrode 42. In this case, the cross section of the second slit 427 is formed in an oval shape. In FIG. 1, the second slit 427 is indicated with a dotted pattern to clearly show its location.

As shown in FIG. 2, the second slit end 429 is an outer edge of a side surface of the second upper electrode 42 that forms the second slit 427 and faces outward in the direction perpendicular to the thickness direction DT, and is in contact with the seventh film 217. Furthermore, in the direction perpendicular to the thickness direction DT, the second slit end 429 is positioned farther outside the second lower electrode 32 than the lower second electrode end 325. In addition, a second slit distance Lsb2 is set to be greater than or equal to 1.0 μm and less than or equal to 50 μm. It should be noted that the second slit distance Lsb2 is the minimum distance from the second slit end 429 to the lower second electrode end 325 in the direction perpendicular to the thickness direction DT.

Furthermore, a distance from the second lower electrode 32 to the surface of the sixth film 216 that faces the second lower electrode 32 in the thickness direction DT is referred to as a lower second distance Lb2. In addition, a distance from the second upper electrode 42 to the surface of the sixth film 216 that faces the second upper electrode 42 in the thickness direction DT is referred to as an upper second distance Lu2.

Then, the upper second distance Lu2 is smaller than the lower second distance Lb2, that is, Lu2<Lb2. Furthermore, the upper second distance Lu2 is set to be the same as the upper first distance Lu1, that is, Lu1=Lu2. Additionally, the lower second distance Lb2 is set to be the same as the lower first distance Lb1, that is, Lb1=Lb2. Here, “the same” is intended to include the range of manufacturing tolerances.

Returning to FIG. 1, the second lead-out wiring 62 is formed together with the first lower electrode 31, the first lead-out wiring 61, and the second lower electrode 32. Furthermore, the second lead-out wiring 62 is made of a metal such as aluminum, tungsten, copper, titanium, or tantalum, and therefore possesses electrical conductivity. The second lead-out wiring 62 includes a second connection portion 621, a third extension portion 622, and a fourth extension portion 623.

The second connection portion 621 is connected to the second lower electrode 32, and in this example, is connected to the lower third curved portion 321. It should be noted that the second connection portion 621 is not limited to being connected to the lower third curved portion 321, and may also be connected to the lower fourth curved portion 322 and the lower second straight portion 323.

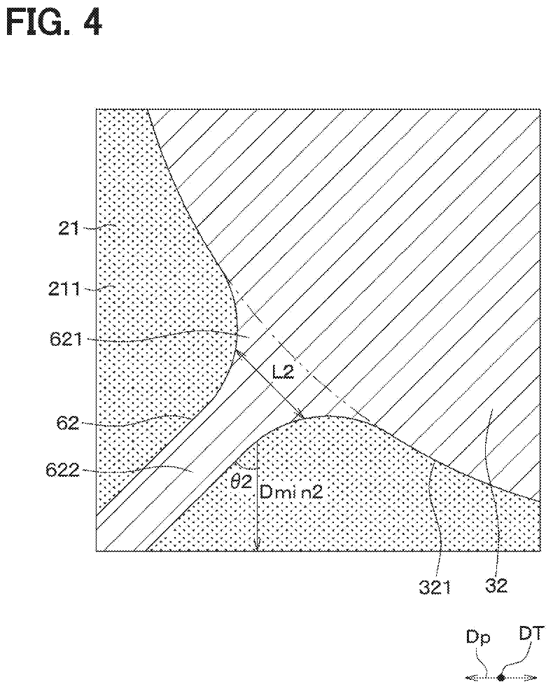

Furthermore, as shown in FIG. 4, an outer edge of the cross section of the second connection portion 621, when cut in the direction perpendicular to the thickness direction DT, is formed in a concavely curved shape. Therefore, the center of curvature of the second connection portion 621 is located outside of the second connection portion 621. In addition, the radius of curvature of the second connection portion 621 is, for example, set to 10 μm. Furthermore, a second length L2 decreases as the second connection portion 621 extends toward the third extension portion 622, which will be described later. It should be noted that the second length L2 is the length of the second connection portion 621 in a direction perpendicular to both the thickness direction DT and the direction in which the third extension portion 622 extends.

The third extension portion 622 is connected to a side of the second connection portion 621 opposite the second lower electrode 32. In addition, the third extension portion 622 extends in a direction intersecting a second shortest direction Dmin2. It should be noted that the second shortest direction Dmin2 is a direction of a shortest line segment connecting the second connection portion 621 and the shield portion 50 in the direction perpendicular to the thickness direction DT. Furthermore, in this example, the third extension portion 622 extends in a straight line. However, the way the third extension portion 622 extends is not limited to this example, and the third extension portion 622 may also extend in a curved shape.

Here, an angle formed by a straight line extending in the second shortest direction Dmin2 and a straight line extending in the direction in which the third extension portion 622 extends is defined as a second angle θ2. The second angle θ2 is set to be greater than or equal to 45 degrees and less than 90 degrees.

As shown in FIG. 1, the fourth extension portion 623 is connected to a side of the third extension portion 622 opposite the second connection portion 621. Furthermore, the fourth extension portion 623 extends in a direction that intersects with the direction in which the third extension portion 622 extends. For example, the fourth extension portion 623 extends in the second shortest direction Dmin2. As a result, the fourth extension portion 623 is connected to the arithmetic circuit 10. Here, the fourth extension portion 623 extends in a straight line. However, the way the fourth extension portion 623 extends is not limited to this example, and the fourth extension portion 623 may also extend in a curved shape.

Here, a direction in which the first lower electrode 31 and the second lower electrode 32 are arranged is defined as a parallel direction Dp. Then, the first extension portion 612 and the third extension portion 622 face each other in the parallel direction Dp. Furthermore, the second extension portion 613 and the fourth extension portion 623 face each other in the parallel direction Dp.

Returning to FIG. 2, the second insulating film 22 has electrical insulating properties, for example, by being made of silicon dioxide or the like. Furthermore, the second insulating film 22 covers an outer peripheral portion of the first upper electrode 41, and also covers a portion of the seventh film 217 around the outer peripheral portion of the first upper electrode 41. Furthermore, the second insulating film 22 covers an outer peripheral portion of the second upper electrode 42, and also covers a portion of the seventh film 217 around the outer peripheral portion of the second upper electrode 42. Furthermore, for example, after a film covering the first upper electrode 41 and the second upper electrode 42 is formed by CVD or the like, thinning and planarization of the film is carried out by CMP or the like. Thereafter, by etching, a portion of the first upper electrode 41 and a portion of the second upper electrode 42 are exposed. Therefore, opening portions are formed in the second insulating film 22. It should be noted that CMP stands for chemical mechanical polishing.

The third insulating film 23, for example, is made of polyimide or the like, and therefore has electrical insulating properties. Furthermore, the insulation withstand voltage of the third insulating film 23 is lower than that of the second insulating film 22.

In addition, the third insulating film 23 covers the outer peripheral portion of the first upper electrode 41 and is also filled in the first slit 417. Furthermore, the third insulating film 23 covers the outer peripheral portion of the second upper electrode 42 and is also filled in the second slit 427. As a result, compared to a case where the third insulating film 23 is not filled in the first slit 417 and the second slit 427, the expansion and contraction of the third insulating film 23 caused by temperature changes in the signal transmission device 5 is less constrained. Therefore, since the thermal stress applied to the third insulating film 23 is alleviated, the stress applied to the second insulating film 22, which is covered with the third insulating film 23, is also alleviated.

In addition, the third insulating film 23 covers the second insulating film 22 as well as the seventh film 217. Furthermore, for example, after the third insulating film 23 is formed by coating or the like, the third insulating film 23 is patterned or otherwise processed to form a predetermined pattern shape. As a result, a portion of the first upper electrode 41 and a portion of the second upper electrode 42 are exposed. Therefore, opening portions are formed in the third insulating film 23.

The signal transmission device 5 is configured as described above. Next, the operation of the signal transmission device 5 will be described.

In the signal transmission device 5, a voltage higher than that applied to the first lower electrode 31 is applied to the first upper electrode 41. In addition, signals from the arithmetic circuit 10 are transmitted to an external device via the second extension portion 613, the first extension portion 612, the first connection portion 611, the first lower electrode 31, the first upper electrode 41, and bonding wires (not shown) connected to the first upper electrode 41. Furthermore, a voltage higher than that applied to the second lower electrode 32 is applied to the second upper electrode 42. In addition, signals from the arithmetic circuit 10 are transmitted to an external device via the fourth extension portion 623, the third extension portion 622, the second connection portion 621, the second lower electrode 32, the second upper electrode 42, and bonding wires (not shown) connected to the second upper electrode 42. The external device may be, for example, an external chip equipped with a drive circuit (not shown). In this case, for example, the drive circuit turns a power switching element (not shown) on and off based on the signals from the arithmetic circuit 10. As a result, for example, a motor or the like is driven.

The signal transmission device 5 operates as described above. Next, the signal transmission device 5 will be described with respect to how the increase in thickness between electrodes is suppressed while ensuring the insulation withstand voltage of the signal transmission device 5.

Here, in a capacitor having a first terminal, a second terminal, and a dielectric material layer disposed between the first terminal and the second terminal, an electric field strength between the first terminal and the second terminal may be reduced by increasing a thickness of the dielectric material layer between the first terminal and the second terminal. Accordingly, an insulation withstand voltage of the capacitor as a signal transmission device can be ensured. However, increasing the thickness of the dielectric material layer increases the number of manufacturing steps, such as forming a large number of vias and wiring layers, in the manufacture of the capacitor. This increases a cost of the capacitor. Furthermore, if the thickness of the dielectric material layer is small, the electric field strength between the first terminal and the second terminal increases, and therefore the insulation withstand voltage of the capacitor cannot be ensured.

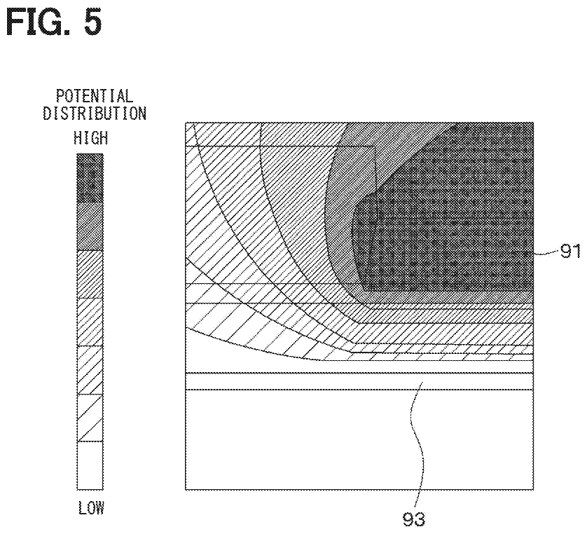

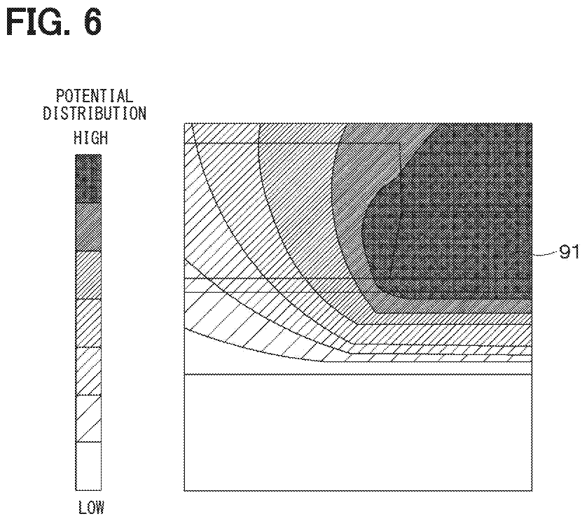

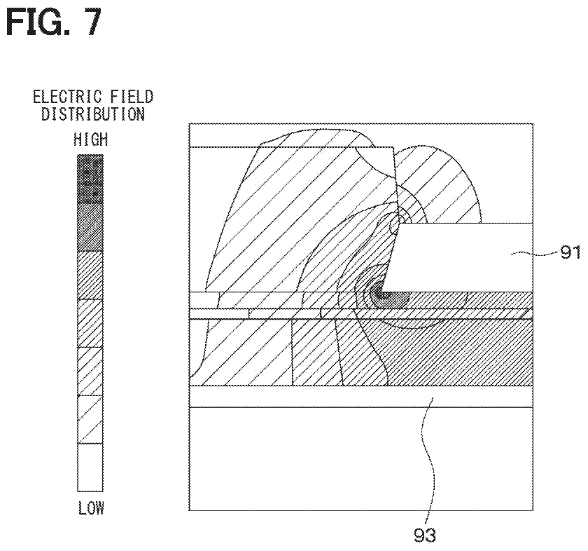

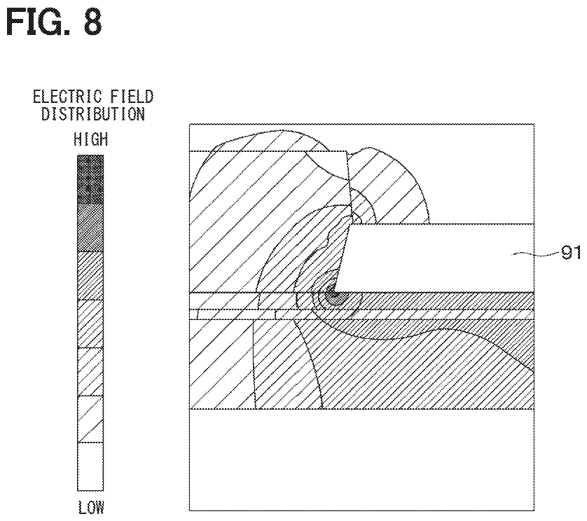

Furthermore, if the thickness of the dielectric material layer is small, when the lead-out wiring is connected to the second terminal, the lead-out wiring and the first terminal are close to each other. Therefore, as shown in FIGS. 5 to 8, for example, when a relatively high voltage is applied to the first terminal 91 of a signal transmission device of a comparative example, the electric field strength between the first terminal 91 and the second terminal increases. Accordingly, the electric field strength between the first terminal 91 and the lead-out wiring 93 also increases. FIG. 5 and FIG. 7 are diagrams showing the potential distribution and the electric field distribution in the vicinity of the first terminal 91 and the lead-out wiring 93 when a voltage of 3250 V is applied between the first terminal 91 and the second terminal. FIG. 6 and FIG. 8 are diagrams showing the potential distribution and the electric field distribution in the vicinity of the first terminal 91 when a voltage of 3250 V is applied between the first terminal 91 and the second terminal.

In contrast, the signal transmission device 5 of the present embodiment includes the first lower electrode 31, the first upper electrode 41, the shield portion 50 and the first lead-out wiring 61. The first upper electrode 41 faces the first lower electrode 31 in the thickness direction DT. Furthermore, a voltage higher than that applied to the first lower electrode 31 is applied to the first upper electrode 41. The shield portion 50 is disposed between the arithmetic circuit 10 and both the first lower electrode 31 and the first upper electrode 41 in the direction perpendicular to the thickness direction DT. Furthermore, the potential of the shield portion 50 is set to the reference potential. It should be noted that the first lower electrode 31 corresponds to a first electrode. The first upper electrode 41 corresponds to a second electrode. The shield portion 50 corresponds to a ground. The first lead-out wiring 61 corresponds to a lead-out portion. The arithmetic circuit 10 corresponds to an electronic circuit.

The first lead-out wiring 61 includes a first connection portion 611, a first extension portion 612, and a second extension portion 613. The first connection portion 611 is connected to the first lower electrode 31. The first extension portion 612 is connected to the first connection portion 611. The second extension portion 613 is connected to the first extension portion 612 and the arithmetic circuit 10.

Furthermore, the first extension portion 612 extends in a direction intersecting the first shortest direction Dmin1. In addition, the second extension portion 613 extends in a direction that intersects with the direction in which the first extension portion 612 extends. For example, the second extension portion 613 extends in the first shortest direction Dmin1. Furthermore, a signal from the arithmetic circuit 10 is transmitted via the second extension portion 613, the first extension portion 612, the first connection portion 611, the first lower electrode 31 and the first upper electrode 41. It should be noted that the first shortest direction Dmin1 is a direction of a shortest line segment connecting the first connection portion 611 and the shield portion 50 in a direction perpendicular to the thickness direction DT.

The strength of the electric field from the first upper electrode 41 is smaller in a direction not directed from the first upper electrode 41 toward the shield portion 50 than in a direction directed from the first upper electrode 41 toward the shield portion 50. Furthermore, since the first extension portion 612 extends in the direction intersecting the first shortest direction Dmin1, the first lead-out wiring 61 extends in the direction not directed from the first upper electrode 41 toward the shield portion 50. Therefore, the electric field strength between the first upper electrode 41 and the first lead-out wiring 61 is smaller than when the first extension portion 612 extends in the first shortest direction Dmin1. Furthermore, it is not necessary to increase the thickness of the first insulating film 21 between the first upper electrode 41 and the first lower electrode 31. Therefore, while suppressing an increase in the thickness between the electrodes, the insulation withstand voltage of the signal transmission device 5 can be ensured.

The signal transmission device 5 also includes the second lower electrode 32, the second upper electrode 42 and the second lead-out wiring 62. The second upper electrode 42 faces the second lower electrode 32 in the thickness direction DT. Furthermore, a voltage higher than that applied to the second lower electrode 32 is applied to the second upper electrode 42. In the direction perpendicular to the thickness direction DT, the shield portion 50 is disposed between the arithmetic circuit 10 and both the second lower electrode 32 and the second upper electrode 42.

The second lead-out wiring 62 includes a second connection portion 621, a third extension portion 622, and a fourth extension portion 623. The second connection portion 621 is connected to the second lower electrode 32. The third extension portion 622 is connected to the second connection portion 621. The fourth extension portion 623 is connected to the third extension portion 622 and the arithmetic circuit 10.

In addition, the third extension portion 622 extends in a direction intersecting the second shortest direction Dmin2. Furthermore, the fourth extension portion 623 extends in the direction that intersects with the direction in which the third extension portion 622 extends. For example, the fourth extension portion 623 extends in the second shortest direction Dmin2. Furthermore, signals from the arithmetic circuit 10 are transmitted via the fourth extension portion 623, the third extension portion 622, the second connection portion 621, the second lower electrode 32 and the second upper electrode 42. It should be noted that the second shortest direction Dmin2 is a direction of a shortest line segment connecting the second connection portion 621 and the shield portion 50 in the direction perpendicular to the thickness direction DT.

Therefore, similarly to the above, while suppressing an increase in the thickness between the electrodes, the insulation withstand voltage of the signal transmission device 5 can be ensured.

In addition, the signal transmission device 5 of the first embodiment also achieves the effects described below.

The first lower electrode 31 has the lower first curved portion 311. The lower first curved portion 311 is formed to be curved toward the arithmetic circuit 10 in the direction perpendicular to the thickness direction DT. The first connection portion 611 is connected to the lower first curved portion 311.

This reduces the length of the first lead-out wiring 61 compared to when the first connection portion 611 is connected to the lower second curved portion 312 and the lower first straight portion 313. Therefore, a parasitic capacitance caused by the first lead-out wiring 61 is reduced. Therefore, the signal-to-noise ratio of the signals from the arithmetic circuit 10 increases. Therefore, the deterioration of the accuracy of the signals from the arithmetic circuit 10 is suppressed.

The second lower electrode 32 also has the lower third curved portion 321. The lower third curved portion 321 is formed so as to be curved toward the arithmetic circuit 10 in the direction perpendicular to the thickness direction DT. Furthermore, the second connection portion 621 is connected to the lower third curved portion 321.

As a result, similarly to the above, a parasitic capacitance caused by the second lead-out wiring 62 is reduced, and the signal-to-noise ratio of the signals from the arithmetic circuit 10 is increased. Therefore, the deterioration of the accuracy of the signals from the arithmetic circuit 10 is suppressed.

Here, when a voltage higher than that applied to the first lower electrode 31 is applied to the first upper electrode 41, the electric field strength in the vicinity of the upper first electrode end 415 becomes relatively high. Therefore, if the minimum distance from the upper first electrode end 415 to the first lower electrode 31 is relatively small, the electric field strength between the first upper electrode 41 and the first lower electrode 31 becomes large. Therefore, at this time, it is difficult to ensure the insulation withstand voltage of the signal transmission device 5.

On the other hand, in the signal transmission device 5, a first upper area Sul is larger than a first lower area Sb1, that is, Su1>Sb1. The first lower area Sb1 is the area of the first lower electrode 31 on a surface perpendicular to the thickness direction DT. The first upper area Su1 is the area of the first upper electrode 41 on a surface perpendicular to the thickness direction DT. The surface of the first lower electrode 31 perpendicular to the thickness direction DT corresponds to a surface of the first electrode intersecting with the thickness direction DT. The surface of the first upper electrode 41 perpendicular to the thickness direction DT corresponds to a surface of the second electrode intersecting with the thickness direction DT. The first lower area Sb1 corresponds to a first area. The first upper area Su1 corresponds to a second area.

In addition, the lower first electrode end 315 is positioned further inside the first upper electrode 41 than the upper first electrode end 415 in the direction perpendicular to the thickness direction DT. The lower first electrode end 315 corresponds to a first end. The upper first electrode end 415 corresponds to a second end.

As a result, compared to a case where the lower first electrode end 315 is positioned further outside than the upper first electrode end 415 in the direction perpendicular to the thickness direction DT, the minimum distance from the upper first electrode end 415 to the first lower electrode 31 becomes greater. Therefore, the electric field strength between the first upper electrode 41 and the first lower electrode 31 is reduced. Therefore, the insulation withstand voltage of the signal transmission device 5 can be easily ensured.

In the signal transmission device 5, the second upper area Su2 is larger than the second lower area Sb2, that is, Su2>Sb2. Furthermore, the lower second electrode end 325 is positioned further inside the second upper electrode 42 than the upper second electrode end 425 in the direction perpendicular to the thickness direction DT.

As a result, the minimum distance from the upper second electrode end 425 to the second lower electrode 32 is reduced, as in the case described above. Therefore, the electric field strength between the second upper electrode 43 and the second lower electrode 32 is reduced. Therefore, the insulation withstand voltage of the signal transmission device 5 can be easily ensured.

When the first inter-electrode distance Lud1 is relatively small, the electric field strength between the first upper electrode 41 and the first lower electrode 31 increases, resulting in a decrease in the insulation withstand voltage of the signal transmission device 5. Furthermore, when the first inter-electrode distance Lud1 is relatively large, the capacitance between the first lower electrode 31 and the first upper electrode 41 decreases, resulting in a decrease in the capacitance of the signal transmission device 5.

In contrast, in the signal transmission device 5, the first inter-electrode distance Lud1 is set to be greater than or equal to 5.0 μm and less than or equal to 8.0 μm. Here, the first inter-electrode distance Lud1 is a distance from the first upper electrode 41 to the first lower electrode 31 in the thickness direction DT, and corresponds to a distance from the first electrode to the second electrode in the thickness direction DT.

Accordingly, the first inter-electrode distance Lud1 is prevented from being excessively small or large, compared to cases where the first inter-electrode distance Lud1 is less than 5.0 μm or greater than 8.0 μm. Therefore, both the insulation withstand voltage and the capacitance of the signal transmission device 5 are ensured.

In addition, in the signal transmission device 5, the second inter-electrode distance Lud2 is set to be greater than or equal to 5.0 μm and less than or equal to 8.0 μm. It should be noted that the second inter-electrode distance Lud2 is a distance from the second upper electrode 42 to the second lower electrode 32 in the thickness direction DT.

Accordingly, the second inter-electrode distance Lud2 is prevented from being excessively small or large, compared to cases where the second inter-electrode distance Lud2 is less than 5.0 μm or greater than 8.0 μm. Therefore, both the insulation withstand voltage and the capacitance of the signal transmission device 5 are ensured.

An outer edge of the cross section of the first connection portion 611, when cut in the direction perpendicular to the thickness direction DT, Is formed in a concavely curved shape. In addition, the first length L1 decreases as the first connection portion 611 extends toward the first extension portion 612. It should be noted that the first length L1 is the length of the first connection portion 611 in a direction perpendicular to both the thickness direction DT and the direction in which the first extension portion 612 extends. Furthermore, the direction perpendicular to the thickness direction DT and the direction in which the first extension portion 612 extends corresponds to the direction intersecting the thickness direction DT and the direction in which the first extension portion 612 extends.

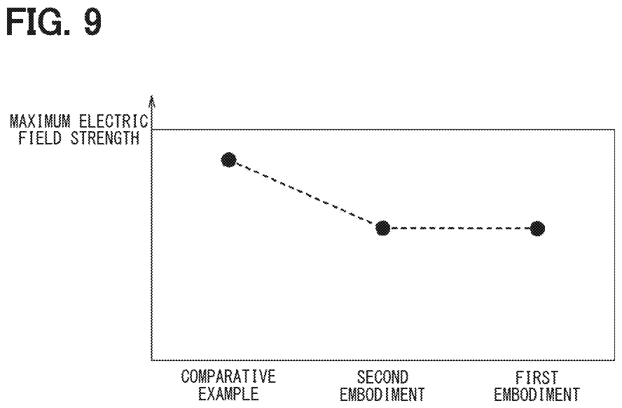

Accordingly, compared to the case where the corner of the first connection portion 611 is a right angle, electric field concentration is less likely to occur in the vicinity of the first connection portion 611. Therefore, as shown in FIG. 9, the maximum electric field strength of the signal transmission device 5 is smaller than when the corner of the first connection portion 611 is a right angle. Therefore, the insulation withstand voltage of the signal transmission device 5 can be easily ensured.

In addition, an outer edge of the cross section of the second connection portion 621, when cut in the direction perpendicular to the thickness direction DT, is formed in a concavely curved shape. Furthermore, the second length L2 decreases as the second connection portion 621 extends toward the third extension portion 622. It should be noted that the second length L2 is the length of the second connection portion 621 in a direction perpendicular to both the thickness direction DT and the direction in which the third extension portion 622 extends.

As a result, similarly to the above, electric field concentration is less likely to occur in the vicinity of the second connection portion 621. Therefore, the maximum electric field strength of the signal transmission device 5 becomes smaller. Therefore, the insulation withstand voltage of the signal transmission device 5 can be easily ensured.

The first angle 01 is greater than or equal to 45 degrees and less than 90 degrees. Note that the first angle θ1 is the angle formed by the straight line extending in the first shortest direction Dmin1 and the straight line extending in the direction in which the first extension portion 612 extends.

As a result, the first extension portion 612 is less likely to extend in the first shortest direction Dmin1. That is, the first extension portion 612 tends to extend in a direction not directed from the first upper electrode 41 toward the shield portion 50. Therefore, the electric field strength in the vicinity of the first lead-out wiring 61 is reduced. Furthermore, since the first extension portion 612 extends toward the arithmetic circuit 10, the length of the second extension portion 613 is shorter than in a case where the first angle 81 is greater than or equal to 90 degrees and less than 180 degrees. Therefore, the length of the first lead-out wiring 61 becomes relatively short. This reduces the parasitic capacitance caused by the first lead-out wiring 61. Therefore, the signal-to-noise ratio of the signals from the arithmetic circuit 10 increases. Therefore, the deterioration of the accuracy of the signals from the arithmetic circuit 10 is suppressed.

The second angle θ2 is greater than or equal to 45 degrees and less than 90 degrees. The second angle θ2 is the angle formed by the straight line extending in the second shortest direction Dmin2 and the straight line extending in the direction in which the third extension portion 622 extends.

As a result, the electric field strength in the vicinity of the second lead-out wiring 62 is reduced in the same manner as described above. Furthermore, compared to when the second angle θ2 is greater than or equal to 90 degrees and less than 180 degrees, the length of the second lead-out wiring 62 is shorter, and therefore the parasitic capacitance caused by the second lead-out wiring 62 is smaller. Therefore, the signal-to-noise ratio of the signals from the arithmetic circuit 10 increases. Therefore, the deterioration of the accuracy of the signals from the arithmetic circuit 10 is suppressed.

The signal transmission device 5 includes the first lower electrode 31, the first upper electrode 41, the second lower electrode 32, the second upper electrode 42, the first lead-out wiring 61 and the second lead-out wiring 62. The first lead-out wiring 61 has the first extension portion 612 and the second extension portion 613. The second lead-out wiring 62 has the third extension portion 622 and the fourth extension portion 623. It should be noted that the second lower electrode 32 corresponds to a third electrode. The second upper electrode 42 corresponds to a fourth electrode. The first lead-out wiring 61 corresponds to a first lead-out portion. The second lead-out wiring 62 corresponds to a second lead-out portion.

In addition, the first extension portion 612 and the third extension portion 622 face each other in the parallel direction Dp. Furthermore, the second extension portion 613 and the fourth extension portion 623 face each other in the parallel direction Dp. The parallel direction Dp is the direction in which the first lower electrode 31 and the second lower electrode 32 are aligned.

As a result, the first lead-out wiring 61 and the second lead-out wiring 62 become closer to each other compared to the case where they are not facing each other. For this reason, it becomes easier to manufacture both the first lead-out wiring 61 and the second lead-out wiring 62. Therefore, the variation resulting from the manufacturing of the first lead-out wiring 61 and the second lead-out wiring 62 becomes smaller compared to the case where the first lead-out wiring 61 and the second lead-out wiring 62 are not facing each other.

### SECOND EMBODIMENT

In a second embodiment, the configurations of the first connection portion 611 and the second connection portion 621 are different from those in the first embodiment. The other configurations are the same as those of the first embodiment.

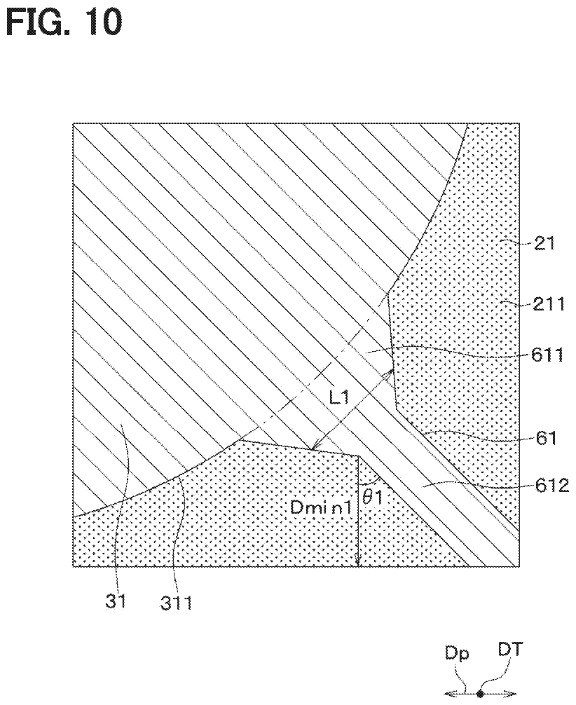

Specifically, as shown in FIG. 10, the cross section of the first connection portion 611 when cut in the direction perpendicular to the thickness direction DT is formed in a trapezoidal shape. In addition, the first length L1 decreases as the first connection portion 611 extends toward the first extension portion 612. As a result, similarly to the above, electric field concentration is less likely to occur in the vicinity of the first connection portion 611. Therefore, as shown in FIG. 9, the maximum electric field strength of the signal transmission device 5 is smaller than when the corner of the first connection portion 611 is a right angle.

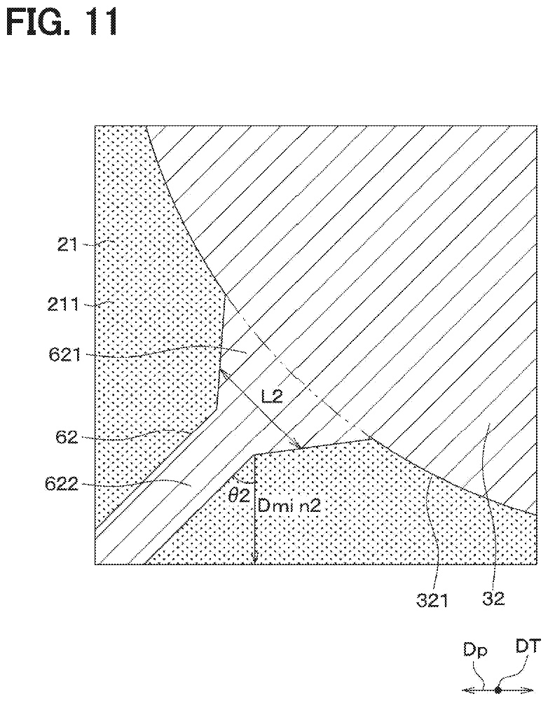

Furthermore, as shown in FIG. 11, the cross section of the second connection portion 621 when cut in the direction perpendicular to the thickness direction DT is formed in a trapezoidal shape. The second length L2 decreases as the second connection portion 621 extends toward the third extension portion 622. As a result, similarly to the above, electric field concentration is less likely to occur in the vicinity of the second connection portion 621. Therefore, the maximum electric field strength of the signal transmission device 5 is smaller than when the corner of the second connection portion 621 is a right angle.

The signal transmission device 5 of the second embodiment is configured as described above. The second embodiment achieves effects similar to the effects achieved by the first embodiment.

### THIRD EMBODIMENT

In a third embodiment, the signal transmission device 5 includes a first arithmetic circuit 11 and a second arithmetic circuit 12 instead of the arithmetic circuit 10. Furthermore, the signal transmission device 5 includes a third lead-out wiring 63 and a fourth lead-out wiring 64 in addition to the first lead-out wiring 61 and the second lead-out wiring 62. The other configurations are similar to those of the first embodiment.

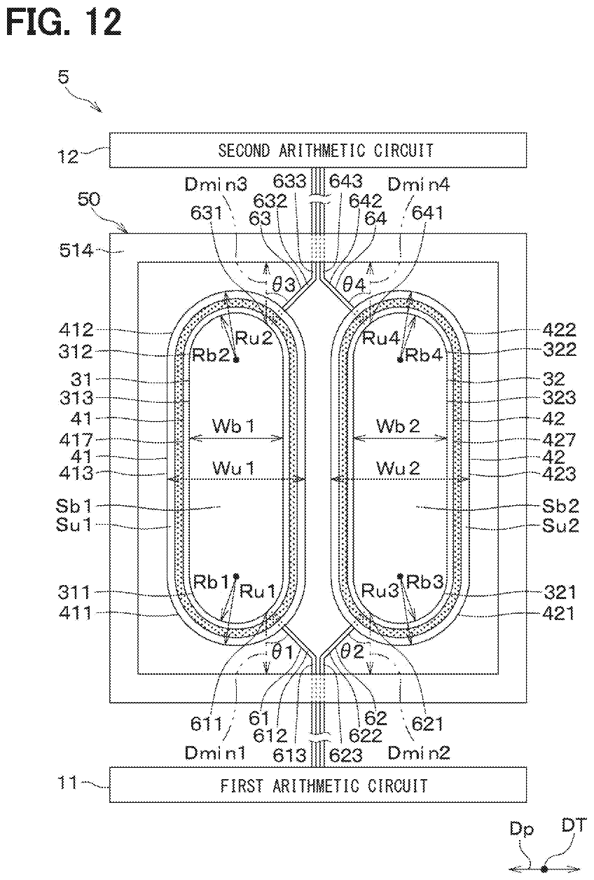

Specifically, the first arithmetic circuit 11 corresponds to a first electronic circuit, and is an electronic circuit, such as a microcomputer, that executes arithmetic operations and logical operations. As shown in FIG. 12, in the direction perpendicular to the thickness direction DT, a portion of the shield portion 50 is arranged between the first arithmetic circuit 11 and each of the first lower electrode 31, the first upper electrode 41, the second lower electrode 32, and the second upper electrode 42.

The second arithmetic circuit 12 corresponds to a second electronic circuit, and is an electronic circuit, such as a microcomputer, that executes arithmetic operations and logical operations. Furthermore, in the direction perpendicular to the thickness direction DT, a portion of the shield portion 50 is arranged between the second arithmetic circuit 12 and each of the first lower electrode 31, the first upper electrode 41, the second lower electrode 32 and the second upper electrode 42. Here, the second arithmetic circuit 12 is located on the opposite side of the first lower electrode 31, the first upper electrode 41, the second lower electrode 32 and the second upper electrode 42 from the first arithmetic circuit 11.

The third lead-out wiring 63 corresponds to a second lead-out portion, and is formed together with the first lower electrode 31, the first lead-out wiring 61, the second lower electrode 32 and the second lead-out wiring 62. Furthermore, the third lead-out wiring 63 is made of a metal such as aluminum, tungsten, copper, titanium, or tantalum, and therefore possesses electrical conductivity. The third lead-out wiring 63 includes a third connection portion 631, a fifth extension portion 632, and a sixth extension portion 633.

The third connection portion 631 is connected to the first lower electrode 31, and in this example, is connected to the lower second curved portion 312. It should be noted that the third connection portion 631 is not limited to being connected to the lower second curved portion 312, and may also be connected to the lower first curved portion 311 and the lower first straight portion 313.

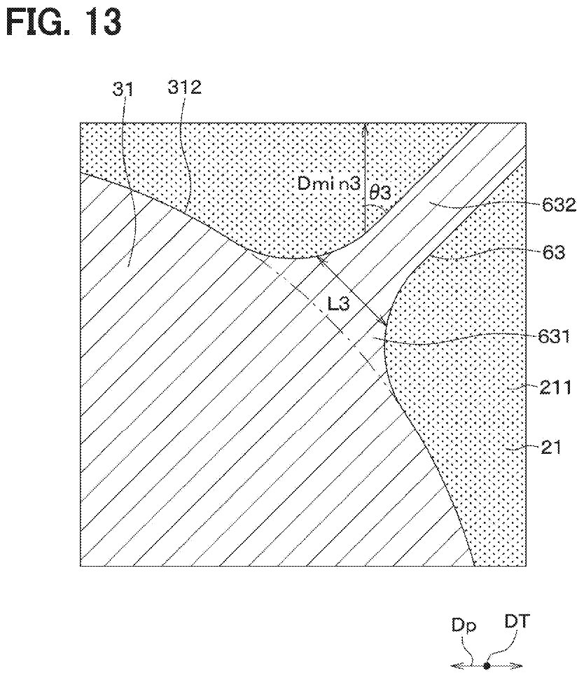

Furthermore, as shown in FIG. 13, an outer edge of the cross section of the third connection portion 631, when cut in the direction perpendicular to the thickness direction DT, is formed in a concavely curved shape. Therefore, the center of curvature of the third connection portion 631 is located outside of the third connection portion 631. In addition, the radius of curvature of the third connection portion 631 is, for example, set to 10 μm. Furthermore, a third length L3 decreases as the third connection portion 631 extends toward the fifth extension portion 632, which will be described later. It should be noted that the third length L3 is the length of the third connection portion 631 in a direction perpendicular to both the thickness direction DT and the direction in which the fifth extension portion 632 extends. In addition, the outer edge of the cross section of the third connection portion 631 when cut in the direction perpendicular to the thickness direction DT is not limited to being formed in the concavely curved shape. For example, the cross section of the third connection portion 631 when cut in the direction perpendicular to the thickness direction DT may be formed into a trapezoidal shape or the like.

The fifth extension portion 632 is connected to a side of the third connection portion 631 opposite the first lower electrode 31. In addition, the fifth extension portion 632 extends in a direction intersecting a third shortest direction Dmin3. It should be noted that the third shortest direction Dmin3 is a direction of a shortest line segment connecting the third connection portion 631 and the shield portion 50 in the direction perpendicular to the thickness direction DT. Furthermore, in this example, the fifth extension portion 632 extends in a straight line. However, the way the fifth extension portion 632 extends is not limited to this example, and the fifth extension portion 632 may also extend in a curved shape.

Here, an angle formed by a straight line extending in the third shortest direction Dmin3 and a straight line extending in the direction in which the fifth extension portion 631 extends is defined as a third angle θ3. The third angle θ3 is set to be greater than or equal to 45 degrees and less than 90 degrees.

As shown in FIG. 1, the sixth extension portion 633 is connected to the side of the fifth extension portion 632 opposite the third connection portion 631. Furthermore, the sixth extension portion 633 extends in a direction that intersects with the direction in which the fifth extension portion 632 extends. For example, the sixth extension portion 633 extends in the third shortest direction Dmin3. As a result, the sixth extension portion 633 is connected to the second arithmetic circuit 12. Here, the sixth extension portion 633 extends in a straight line. However, the way the sixth extension portion 633 extends is not limited to this example, and the sixth extension portion 633 may also extend in a curved shape.

The fourth lead-out wiring 64 is formed together with the first lower electrode 31, the second lower electrode 32, the first lead-out wiring 61, the second lead-out wiring 62 and the third lead-out wiring 63. Furthermore, the fourth lead-out wiring 64 is made of a metal such as aluminum, tungsten, copper, titanium, or tantalum. The fourth lead-out wiring 64 includes a fourth connection portion 641, a seventh extension portion 642, and an eighth extension portion 643.

The fourth connection portion 641 is connected to the second lower electrode 32, and in this example, is connected to the lower fourth curved portion 322. It should be noted that the fourth connection portion 641 is not limited to being connected to the lower fourth curved portion 322, and may also be connected to the lower third curved portion 321 and the lower second straight portion 323.

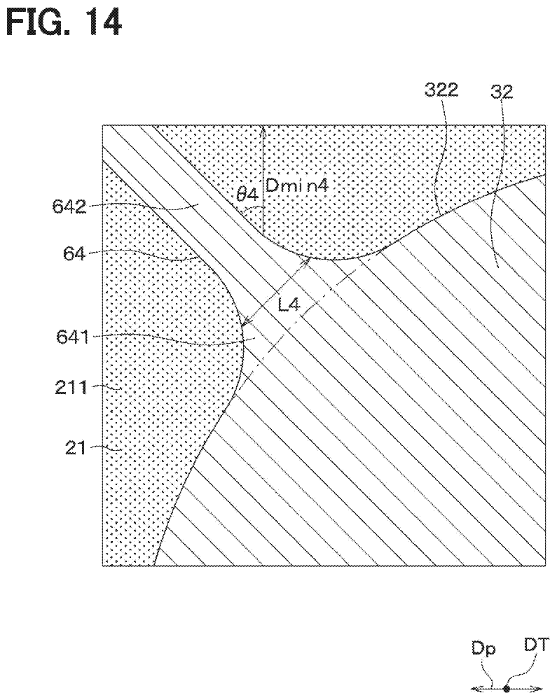

Furthermore, as shown in FIG. 14, an outer edge of the cross section of the fourth connection portion 641, when cut in the direction perpendicular to the thickness direction DT, is formed in a concavely curved shape. Therefore, the center of curvature of the fourth connection portion 641 is located outside of the fourth connection portion 641. In addition, the radius of curvature of the fourth connection portion 641 is, for example, set to 10 μm. Furthermore, a fourth length L4 decreases as the fourth connection portion 641 extends toward the seventh extension portion 642, which will be described later. It should be noted that the fourth length L4 is the length of the fourth connection portion 641 in a direction perpendicular to both the thickness direction DT and the direction in which the seventh extension portion 642 extends. In addition, the outer edge of the cross section of the fourth connection portion 641 when cut in the direction perpendicular to the thickness direction DT is not limited to being formed in the concavely curved shape. For example, the cross section of the fourth connection portion 641 when cut in the direction perpendicular to the thickness direction DT may be formed into a trapezoidal shape or the like.

The seventh extension portion 642 is connected to a side of the fourth connection portion 641 opposite the second lower electrode 32. In addition, the seventh extension portion 642 extends in a direction intersecting a fourth shortest direction Dmin4. It should be noted that the fourth shortest direction Dmin4 is a direction of a shortest line segment connecting the fourth connection portion 641 and the shield portion 50 in the direction perpendicular to the thickness direction DT. Furthermore, in this example, the seventh extension portion 642 extends in a straight line. However, the way the seventh extension portion 642 extends is not limited to this example, and the seventh extension portion 642 may also extend in a curved shape.

Here, an angle formed by a straight line extending in the fourth shortest direction Dmin4 and a straight line extending in the direction in which the seventh extension portion 642 extends is defined as a fourth angle θ4. The fourth angle θ4 is set to be greater than or equal to 45 degrees and less than 90 degrees.

As shown in FIG. 12, the eighth extension portion 643 is connected to the side of the seventh extension portion 642 opposite the fourth connection portion 641. Furthermore, the eighth extension portion 643 extends in a direction that intersects with the direction in which the seventh extension portion 642 extends. For example, the eighth extension portion 643 extends in the fourth shortest direction Dmin4. As a result, the eighth extension portion 643 is connected to the second arithmetic circuit 12. Here, the eighth extension portion 643 extends in a straight line. However, the way the eighth extension portion 643 extends is not limited to this example, and the eighth extension portion 643 may also extend in a curved shape.

In addition, the fifth extension portion 632 and the seventh extension portion 642 face each other in the parallel direction Dp. Furthermore, the sixth extension portion 633 and the eighth extension portion 643 face each other in the parallel direction Dp.

The signal transmission device 5 of the third embodiment is configured as described above. The third embodiment achieves effects similar to the effects achieved by the first embodiment.

### FOURTH EMBODIMENT

In a fourth embodiment, the configurations of the first connection portion 611 and the second connection portion 621 are different from those in the first embodiment. The other configurations are the same as those of the first embodiment.

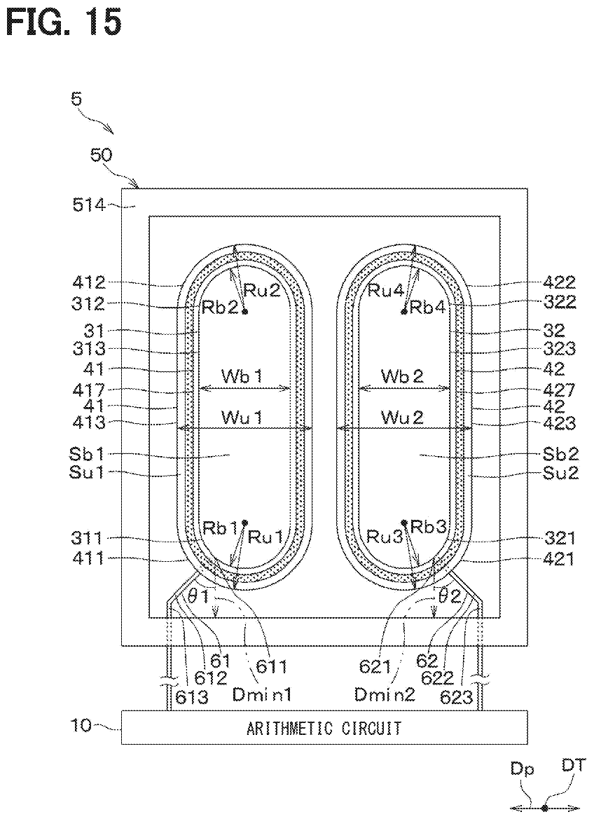

Specifically, as shown in FIG. 15, the first connection portion 611 is connected to a side of the lower first curved portion 311 opposite the second lower electrode 32.

The second connection portion 621 is connected to a side of the lower third curved portion 321 opposite the first lower electrode 31. Therefore, the first connection portion 611 and the second connection portion 621 do not face each other in the parallel direction Dp. Furthermore, the second extension portion 613 and the fourth extension portion 623 face each other in the parallel direction Dp.

The signal transmission device 5 of the fourth embodiment is configured as described above. The fourth embodiment achieves effects similar to the effects achieved by the first embodiment.

### FIFTH EMBODIMENT

In the first embodiment, the signal transmission device 5 is provided with the first lower electrode 31, the first upper electrode 41, the first lead-out wiring 61, the second lower electrode 32, the second upper electrode 42, and the second lead-out wiring 62, and includes two capacitors.

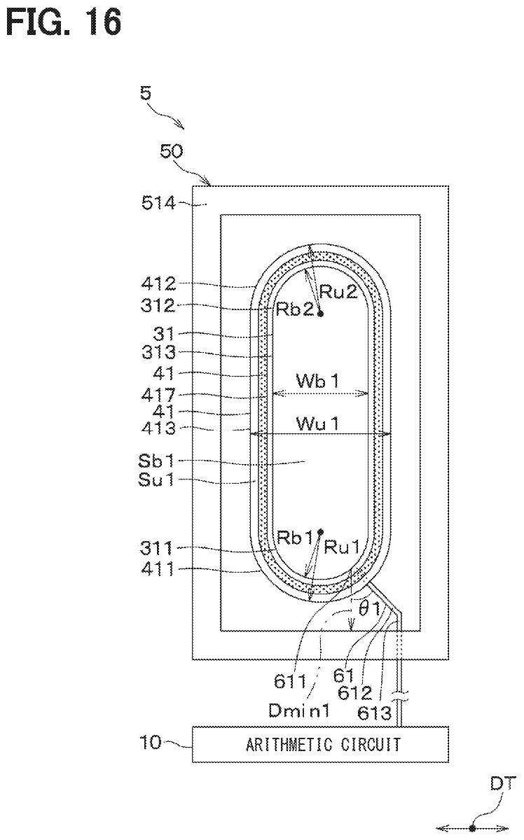

On the other hand, in the fifth embodiment, as shown in FIG. 16, the signal transmission device 5 does not include the second lower electrode 32, the second upper electrode 42, and the second lead-out wiring 62. Therefore, the signal transmission device 5 includes a single capacitor. Furthermore, for this reason, the size of the shield portion 50 is adjusted. The other configurations are the same as those of the first embodiment. The fifth embodiment achieves effects similar to the effects achieved by the first embodiment.

### OTHER EMBODIMENTS

The present disclosure is not limited to the above-described embodiments, and the above-described embodiments can be appropriately modified. The constituent element(s) of each of the above embodiments is/are not necessarily essential unless it is specifically stated that the constituent element(s) is/are essential in the above embodiment, or unless the constituent element(s) is/are obviously essential in principle.

In each of the above-described embodiments, in the cross-sectional view obtained by cutting in the direction perpendicular to the thickness direction DT, the first lower electrode 31, the first upper electrode 41, the second lower electrode 32, and the second upper electrode 42 are formed in the oval shape. However, in the cross-sectional view obtained by cutting in the direction perpendicular to the thickness direction DT, the first lower electrode 31, the first upper electrode 41, the second lower electrode 32, and the second upper electrode 42 are not limited to being formed in the oval shape. In the cross-sectional view obtained by cutting in the direction perpendicular to the thickness direction DT, the first lower electrode 31, the first upper electrode 41, the second lower electrode 32, and the second upper electrode 42 may be formed in polygonal shapes with five or more sides, star shapes, circular shapes, elliptical shapes, or the like.

In each of the above-described embodiments, in the cross-sectional view obtained by cutting in the direction perpendicular to the thickness direction DT, the first slit 417 and the second slit 427 are formed in the oval shape. However, in the cross-sectional view obtained by cutting in the direction perpendicular to the thickness direction DT, the first slit 417 and the second slit 427 are not limited to being formed in the oval shape. In the cross-sectional view obtained by cutting in the direction perpendicular to the thickness direction DT, the first slit 417 and the second slit 427 may be formed in polygonal shapes, star shapes, circular shapes, elliptical shapes, or the like.

In each of the above-described embodiments, the number of capacitors is one or two. The number of capacitors is not limited to one or two, and may be three or more.

In the above-described embodiments, the insulation withstand voltage of the third insulating film 23 is lower than that of the second insulating film 22. However, the insulation withstand voltage of the third insulating film 23 may be equal to or higher than that of the second insulating film 22.

In each of the above-described embodiments, the first upper area Su1 is larger than the first lower area Sb1. However, the first upper area Su1 is not limited to being larger than the first lower area Sb1. The first upper area Su1 may be equal to or smaller than the first lower area Sb1. Therefore, the lower first electrode end 315 may be located further outside the first upper electrode 41 than the upper first electrode end 415 in the direction perpendicular to the thickness direction DT.

The second upper area Su2 is larger than the second lower area Sb2. On the other hand, the second upper area Su2 is not limited to being larger than the second lower area Sb2. The second upper area Su2 may be equal to or smaller than the second lower area Sb2. Therefore, the lower second electrode end 325 may be located further outside the second upper electrode 42 than the upper second electrode end 425 in the direction perpendicular to the thickness direction DT.

The above-described embodiments may be combined as appropriate.

What is claimed is:

1. A signal transmission device comprising:
a semiconductor substrate;
an insulating film having electrical insulating properties and disposed on the semiconductor substrate;
a first electrode covered with the insulating film; and
a second electrode disposed on the insulating film, facing the first electrode in a thickness direction of the semiconductor substrate, and to which a voltage higher than a voltage applied to the first electrode is to be applied, wherein
the first electrode has a first end positioned at an outer edge of a surface of the first electrode that faces the second electrode in the thickness direction,
the second electrode has a second end positioned at an outer edge of the second electrode in a direction perpendicular to the thickness direction that is in contact with the insulating film,
the first end is positioned further inside the second electrode than the second end in the direction perpendicular to the thickness direction, and
a distance from the first end to the second end in the direction perpendicular to the thickness direction is set to be greater than or equal to 10 μm.

2. A signal transmission device comprising:
a semiconductor substrate;
an insulating film having electrical insulating properties and disposed on the semiconductor substrate;
a first electrode covered with the insulating film; and
a second electrode disposed on the insulating film, facing the first electrode in a thickness direction of the semiconductor substrate, and to which a voltage higher than a voltage applied to the first electrode is to be applied, wherein
the first electrode has an electrode end positioned at an outer edge of a surface of the first electrode that faces the second electrode in the thickness direction,
the second electrode has a slit penetrating through the second electrode in the thickness direction, and a slit end positioned at an outer edge of a side surface of the second electrode that forms the slit and faces outward in the direction perpendicular to the thickness direction,
the slit end is in contact with the insulating film, and
the slit end is positioned farther outside the first electrode than the electrode end in the direction perpendicular to the thickness direction.

3. The signal transmission device according to claim 2, wherein
a distance from the slit end to the electrode end in the direction perpendicular to the thickness direction is set to be greater than or equal to 1.0 μm.

4. The signal transmission device according to claim 1, wherein
a distance from the first electrode to the second electrode in the thickness direction is set to be greater than or equal to 5.0 μm and less than or equal to 8.0 μm.

5. The signal transmission device according to claim 1, wherein
the first electrode has a first curved portion that is convexly curved in the direction perpendicular to the thickness direction, and
the second electrode has a second curved portion that is convexly curved in the direction perpendicular to the thickness direction.

6. The signal transmission device according to claim 5, wherein
the first electrode has an oval shape such that the first curved portion has an arc shape,
the first electrode has a first straight portion that is connected to the first curved portion and extends in one direction perpendicular to the thickness direction,
a radius of the first curved portion is set to be greater than or equal to 20 μm and less than or equal to half of a length of the first straight portion in a direction perpendicular to both the thickness direction and the one direction in which the first straight portion extends,
the second electrode has an oval shape such that the second curved portion has an arc shape,
the second electrode has a second straight portion that is connected to the second curved portion and extends in the one direction, and
a radius of the second curved portion is set to be greater than or equal to 20 μm and less than or equal to half of a length of the second straight portion in a direction perpendicular to both the thickness direction and the one direction in which the second straight portion extends.

7. The signal transmission device according to claim 1, wherein
the insulating film includes:
a first layer connected to the second electrode in the thickness direction;
a second layer connected to a surface of the first layer opposite the second electrode in the thickness direction; and
a third layer connected to a surface of the second layer opposite the first layer in the thickness direction, and also connected to the first electrode in the thickness direction,
the first layer is an oxide film,
the second layer is a nitride film, and
the third layer is an oxide film.

8. The signal transmission device according to claim 1, wherein
the insulating film includes:
a first layer connected to the second electrode in the thickness direction;
a second layer connected to a surface of the first layer opposite the second electrode in the thickness direction; and
a third layer connected to a surface of the second layer opposite the first layer in the thickness direction, and also connected to the first electrode in the thickness direction,
the first layer is a nitride film,
the second layer is an oxide film, and
the third layer is an oxide film.

9. The signal transmission device according to claim 1, wherein
the insulating film includes:
a first layer connected to the second electrode in the thickness direction;
a second layer connected to a surface of the first layer opposite the second electrode in the thickness direction; and
a third layer connected to a surface of the second layer opposite the first layer in the thickness direction, and also connected to the first electrode in the thickness direction,
the first layer is an oxide film,
the second layer is an oxide film, and
the third layer is a nitride film.

10. The signal transmission device according to claim 1, wherein
the insulating film includes:
a first layer connected to the second electrode in the thickness direction;
a second layer connected to a surface of the first layer opposite the second electrode in the thickness direction; and
a third layer connected to a surface of the second layer opposite the first layer in the thickness direction, and also connected to the first electrode in the thickness direction,
the first layer is a resin film,
the second layer is a nitride film, and
the third layer is an oxide film.

11. The signal transmission device according to claim 7, wherein
a distance in the thickness direction from the second electrode to a surface of the second layer that faces the second electrode is smaller than a distance in the thickness direction from the first electrode to a surface of the second layer that faces the first electrode.

12. The signal transmission device according to claim 2, wherein
a distance from the first electrode to the second electrode in the thickness direction is set to be greater than or equal to 5.0 μm and less than or equal to 8.0 μm.

13. The signal transmission device according to claim 2, wherein
the first electrode has a first curved portion that is convexly curved in the direction perpendicular to the thickness direction, and
the second electrode has a second curved portion that is convexly curved in the direction perpendicular to the thickness direction.

14. The signal transmission device according to claim 13, wherein
the first electrode has an oval shape such that the first curved portion has an arc shape,
the first electrode has a first straight portion that is connected to the first curved portion and extends in one direction perpendicular to the thickness direction,
a radius of the first curved portion is set to be greater than or equal to 20 μm and less than or equal to half of a length of the first straight portion in a direction perpendicular to both the thickness direction and the one direction in which the first straight portion extends,
the second electrode has an oval shape such that the second curved portion has an arc shape,
the second electrode has a second straight portion that is connected to the second curved portion and extends in the one direction, and
a radius of the second curved portion is set to be greater than or equal to 20 μm and less than or equal to half of a length of the second straight portion in a direction perpendicular to both the thickness direction and the one direction in which the second straight portion extends.

15. The signal transmission device according to claim 2, wherein
the insulating film includes:
a first layer connected to the second electrode in the thickness direction;
a second layer connected to a surface of the first layer opposite the second electrode in the thickness direction; and
a third layer connected to a surface of the second layer opposite the first layer in the thickness direction, and also connected to the first electrode in the thickness direction,
the first layer is an oxide film,
the second layer is a nitride film, and
the third layer is an oxide film.

16. The signal transmission device according to claim 2, wherein
the insulating film includes:
a first layer connected to the second electrode in the thickness direction;
a second layer connected to a surface of the first layer opposite the second electrode in the thickness direction; and
a third layer connected to a surface of the second layer opposite the first layer in the thickness direction, and also connected to the first electrode in the thickness direction,
the first layer is a nitride film,
the second layer is an oxide film, and
the third layer is an oxide film.

17. The signal transmission device according to claim 2, wherein
the insulating film includes:
a first layer connected to the second electrode in the thickness direction;
a second layer connected to a surface of the first layer opposite the second electrode in the thickness direction; and
a third layer connected to a surface of the second layer opposite the first layer in the thickness direction, and also connected to the first electrode in the thickness direction,
the first layer is an oxide film,
the second layer is an oxide film, and
the third layer is a nitride film.

18. The signal transmission device according to claim 2, wherein
the insulating film includes:
a first layer connected to the second electrode in the thickness direction;
a second layer connected to a surface of the first layer opposite the second electrode in the thickness direction; and
a third layer connected to a surface of the second layer opposite the first layer in the thickness direction, and also connected to the first electrode in the thickness direction,
the first layer is a resin film,
the second layer is a nitride film, and
the third layer is an oxide film.

19. The signal transmission device according to claim 15, wherein
a distance in the thickness direction from the second electrode to a surface of the second layer that faces the second electrode is smaller than a distance in the thickness direction from the first electrode to a surface of the second layer that faces the first electrode.
